(19) United States
(12) Patent Application Publication
(10) Pub. No.: US 2008/0128901 A1
(43) Pub. Date: Jun. 5, 2008

(54) Micro-electro-mechanical systems device and integrated circuit device integrated in a three-dimensional semiconductor structure

(76) Inventors: Peter Zurcher, Phoenix, AZ (US); Carl E. D'Acosta, Mesa, AZ (US); Thomas P. Remmel, Mesa, AZ (US)

Correspondence Address: INGRASSIA FISHER & LORENZ, P.C. (FS), 7010 E. COCHISE ROAD, SCOTTSDALE, AZ, 85253, US

(21) Appl. No.: 11/606,739

(22) Filed: Nov. 30, 2006

(51) Int. Cl. H01L 23/538; H01L 21/50; H01L 23/64

(52) U.S. Cl. 257/724; 438/455; 257/415; 438/456; 438/107; 257/E21.499; 257/E23.173

(57) ABSTRACT

Semiconductor devices (300, 400, and 500) including an integrated circuit (IC) device (100) coupled to a micro-electro-mechanical systems (MEMS) device (200) and a method (600) for producing same are disclosed. The IC device includes a die seal ring (130) and the MEMS device includes a MEMS seal ring (230), and the IC device is coupled to the MEMS device via the die seal ring and the MEMS seal ring. The MEMS device may include one or more passive devices (450, 475) coupled to it. Moreover, a substrate (510) including an aperture (550) may be coupled to the passive device, wherein the aperture enables the passive device to be trimmed after being disposed on the MEMS device. The semiconductor devices include an RF signal path (486) and at least one other signal path (482 and 484), wherein the other signal path(s) may be an analog and/or a digital signal path.

### FIELD OF THE INVENTION

The present invention generally relates to semiconductor devices, and more particularly relates to a micro-electro-mechanical systems (MEMS) device and integrated circuit (IC) device three-dimensionally integrated to form a semiconductor system in module form.

### BACKGROUND OF THE INVENTION

Reducing the size and cost of semiconductor devices has been one focus of semiconductor research for many years. The desirability of integrating MEMS devices and IC devices is known in the art. However, current co-integration techniques aimed at producing an integrated device are inadequate for a variety of reasons. First, MEMS-on-top-of-CMOS co-integration requires low temperature MEMS processing, which is not optimal and results in device that does not deliver the required performance for an integrated MEMS/CMOS device. Second, MEMS-CMOS co-integration requires changes to the CMOS formation process to accommodate the MEMS formation process, which affects the performance of the CMOS device. Third, typical three-dimensional integration techniques result in large form-factor and are relatively expensive. Finally, typical direct MEMS-CMOS co-integration techniques have a relatively low yield or, in other words, a high failure rate.

Accordingly, it is desirable to produce an integrated MEMS and IC device with improved performance that is less expensive to manufacture and which produces a higher yield than current integrated devices. In addition, it is desirable to implement methods for producing such an improved integrated device. Furthermore, other desirable features and characteristics of the present invention will become apparent from the subsequent detailed description and the appended claims, taken in conjunction with the accompanying drawings and this background.

### BRIEF DESCRIPTION OF THE DRAWINGS

The present invention will hereinafter be described in conjunction with the following drawing figures, wherein like numerals denote like elements, and

FIG. 1 is a diagram illustrating one embodiment of an integrated circuit (IC) device including a die seal ring;

FIG. 2 is a diagram illustrating an embodiment of a micro-electro-mechanical systems (MEMS) device including a plurality of conductors suitable for coupling the MEMS device to the IC device of FIG. 1;

FIG. 3 is a diagram illustrating the IC device of FIG. 1 and the MEMS device of FIG. 2 integrated via the die seal ring and the plurality of conductors to form one embodiment of a three-dimensional (3-D) semiconductor device;

FIG. 4 is a diagram illustrating one embodiment of the 3-D semiconductor device of FIG. 3 including separate radio frequency and direct current (DC) terminals, and integrated passive devices;

FIG. 5 is a diagram illustrating an embodiment of the 3-D semiconductor device of FIG. 4 including a trim-able passive device disposed on a back-side of the MEMS device, mounted on a substrate with an access aperture for trimming the passive device; and

FIG. 6 is a flow diagram illustrating a representation of one embodiment of a method to produce the 3-D semiconductor device of FIG. 3, FIG. 4, and/or FIG. 5.

### DETAILED DESCRIPTION OF THE INVENTION

The following detailed description is merely exemplary in nature and is not intended to limit the various embodiments or the application and uses of the various embodiments disclosed below. Furthermore, there is no intention to be bound by any theory presented in the preceding background or the following detailed description.

FIG. 1 is a diagram illustrating one embodiment of an integrated circuit (IC) device 100 including a substrate 110 that forms a back side 105 of IC device 100, wherein substrate 110 may be either a p-type or an n-type substrate. Substrate 110 may be any material known in the art or developed in the future upon which a semiconductor device may be fabricated. Furthermore, substrate 110 may be comprised of any suitable material known in the art or developed in the future for manufacturing semiconductor devices including, for example, a ceramic, a glass, and a semiconductor (e.g., Si, Ge, GaAs, and the like). Moreover, in one embodiment, substrate 110 is a bulk configuration, whereas in another embodiment substrate 110 includes a semiconductor on insulator (SOI) configuration.

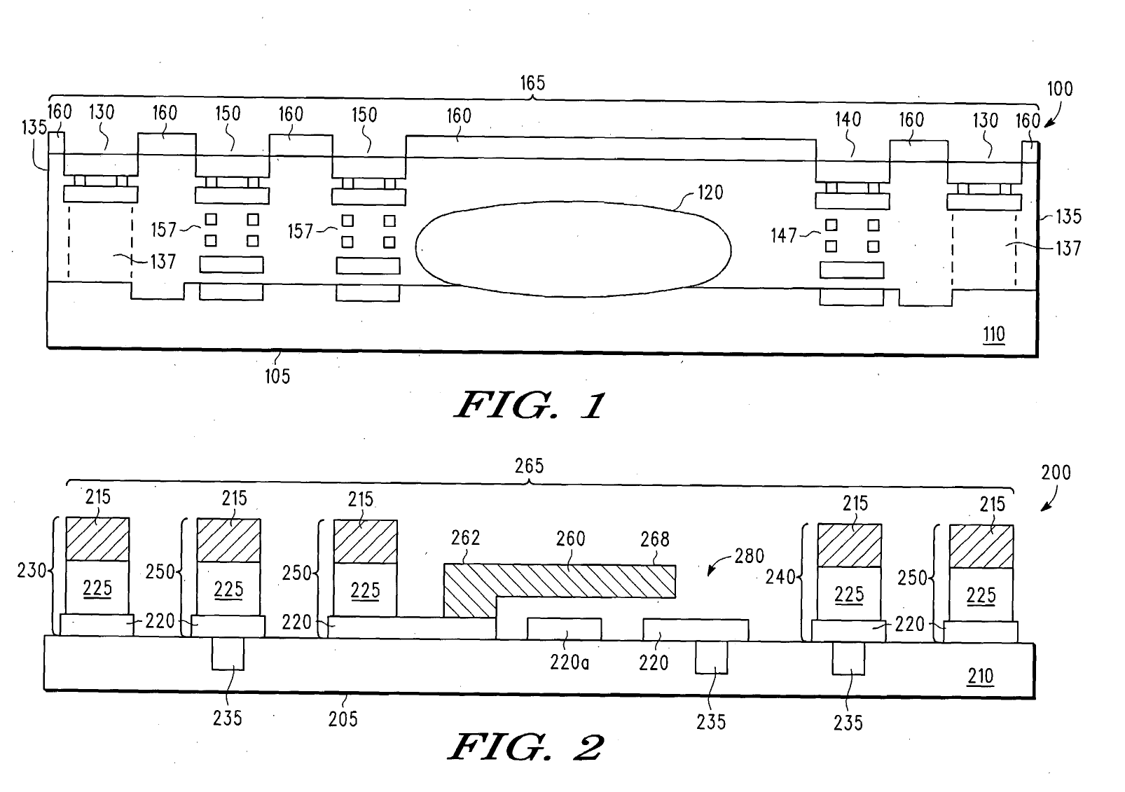

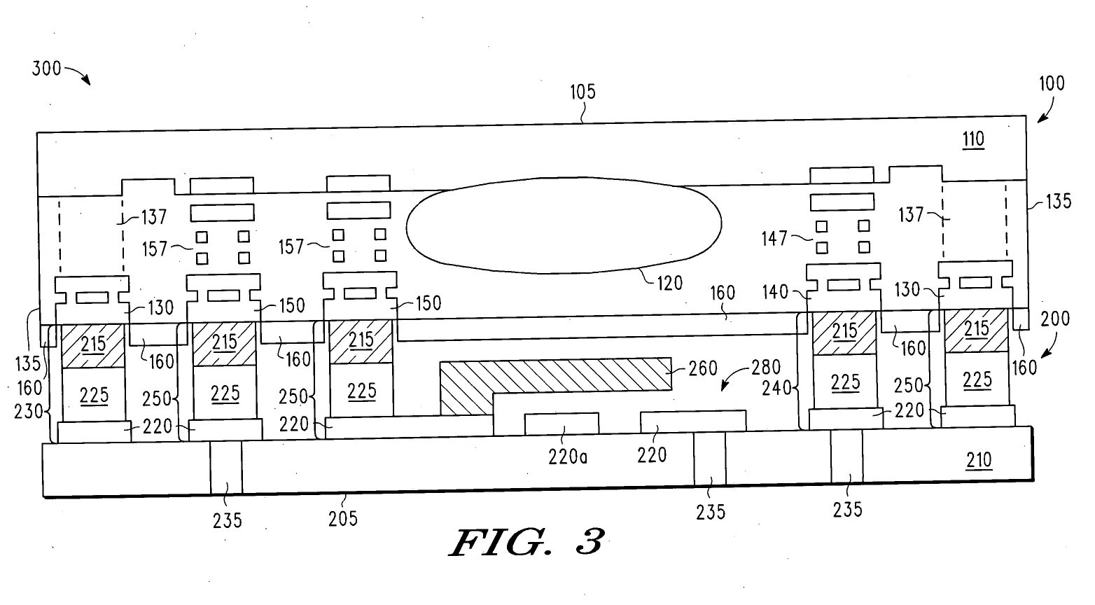

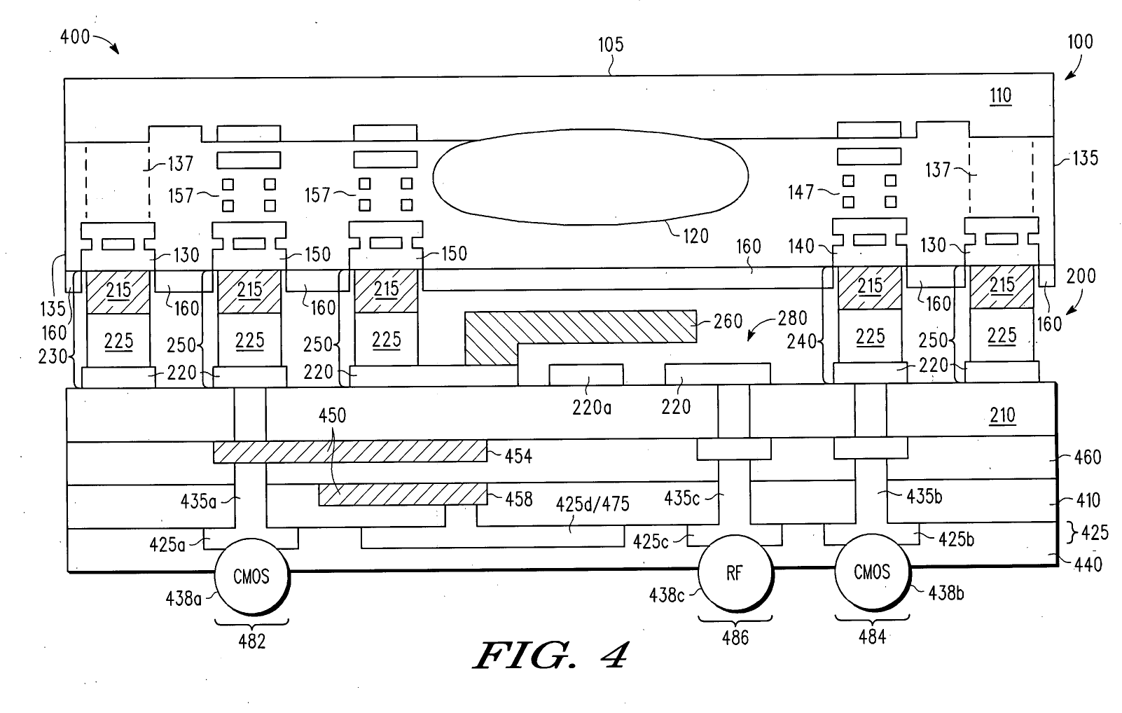

In accordance with one embodiment, IC device 100 includes drive circuitry 120 disposed on substrate 110. Drive 120 may be any drive circuitry and/or other circuitry suitably configured to generate signals to control a semiconductor device with which drive circuitry 120 is coupled. In one embodiment, drive circuitry 120 is circuitry configured to generate signals to control a micro-electro-mechanical systems (MEMS) device (discussed below with reference to FIGS. 2 and 3). Furthermore, drive circuitry 120 may be implemented with transistors, diodes, or other circuitry having active regions. Examples of signals capable of being generated by drive circuitry 120 include, but are not limited to, analog signals, digital signals, radio frequency (RF) signals, alternating current (AC) signals, direct current (DC) signals, and/or the like signals.

IC device 100, in another embodiment, includes a die seal ring 130. Die seal ring 130 circumscribes the periphery 135 of IC device 100 and is in contact with IC device 100. Moreover, die seal ring 130 typically surrounds any bonding pads (not shown) included on IC device 100, which bond pads are disposed along the outer edges of IC device 100. Die seal ring 130 may be any device, material, and/or structure suitably configured to reduce cracking during singulation and penetration of moisture, corrosive gasses, chemicals, and/or other harmful materials during manufacture of IC device 100, and may be disposed on IC device 100 utilizing techniques known in the art.

In one embodiment, die seal ring 130 is a multi-layer structure comprising layers 137 of dielectrics with embedded conducting structures (e.g., metal lines and vias). Die seal ring 130, in accordance with one embodiment, is formed of copper or a copper alloy. Other suitable materials for forming die seal ring 130 include, but are not limited to, aluminum, aluminum-copper, tungsten, tantalum, tantalum-nitride, gold, and the like, including alloys thereof. Through each of the insulating layers may run multiple vias (not shown) which provide electrical paths between adjacent metal layers. The lowest layer of metal in die seal ring 130 makes electrical contact with substrate 110.

Die seal ring 130, in accordance with one embodiment, is suitably configured to couple IC device 100 to another device (e.g., MEMS device 200, discussed below). Moreover, die seal ring 130 is suitably configured to enable the device (e.g., MEMS device 200) with which IC device 100 is coupled to be either hermetically sealed or vacuum sealed utilizing known processes when coupled to IC device 100. Accordingly, die seal ring 130 is configured to include a structure that both protects IC device 100 during manufacture and is compatible with another device (e.g., MEMS device 200) such that the other device can be coupled to IC device 100 via die seal ring 130 and the other device can become hermetically sealed or vacuum sealed when the other device is coupled to IC device 100 via die seal ring 130.

IC device 100, in one embodiment, includes at least one interconnect 140. Interconnect 140 may be any device, material, and/or structure suitably configured to electrically couple IC device 100 to another device (e.g., MEMS device 200, discussed below with reference to FIG. 3) and relay signals from such device to IC device 100. In one embodiment, interconnect 140 is a multi-layer structure comprising layers 147 of dielectrics with embedded conducting structures (e.g., metal lines and vias), wherein a top metal layer of layers 147 forms an interconnect pad. Through each of the insulating layers run multiple vias (not shown) which provide electrical paths between adjacent metal layers. The lowest layer of metal in interconnect 140 makes electrical contact with substrate 110.

Interconnect 140, in accordance with one embodiment, is configured to couple IC device 100 to a controller (not shown) and the signals relayed by interconnect 140 are signals to control IC device 100. In another embodiment, interconnect 140 is configured to couple IC device 100 to a controller and relay direct current (DC) control signals (e.g., CMOS control signals) to drive circuitry 120. The DC control signals, in one embodiment, are digital signals. In the embodiment illustrated in FIG. 1, IC device 100 includes one interconnect 140; however, various embodiments of IC device 100 contemplate that IC device 100 may include any number of interconnect pads 140. Moreover, various embodiments contemplate that interconnect 140 may be configured to relay signals other than DC control signals and/or digital signals.

IC device 100, in one embodiment, includes at least one interconnect 150. Interconnect 150 may be any device, material, and/or structure suitably configured to couple IC device 100 to another device (e.g., MEMS device 200, discussed below with reference to FIG. 3) and relay signals from such device to IC device 100. In one embodiment, interconnect 150 is a multi-layer structure comprising layers 157 of dielectrics with embedded conducting structures (e.g., metal lines and vias), wherein a top metal layer of layers 157 forms an interconnect pad. Through each of the insulating layers may run multiple vias (not shown) which provide electrical paths between adjacent metal layers. The lowest layer of metal in interconnect 150 makes electrical contact with substrate 110.

Interconnect 150, in accordance with one embodiment, is configured to couple IC device 100 to a controller (not shown) and the signals relayed by interconnect 150 are signals to control IC device 100. In another embodiment, interconnect 150 is configured to couple IC device 100 to a controller and relay direct current (DC) control signals (e.g., CMOS control signals) to drive circuitry 120. The DC control signals, in one embodiment, are analog signals. In the embodiment illustrated in FIG. 1, IC device 100 includes two interconnect pads 150; however, various embodiments of IC device 100 contemplate that IC device 100 may include any number of interconnect pads 150. Moreover, various embodiments contemplate that interconnect 150 may be configured to relay signals other than DC control signals, analog signals, and/or sensor signals from a MEMS device.

Interconnect pad(s) 140 and interconnect pad(s) 150 may be formed utilizing techniques known in the art. Moreover, interconnect pad(s) 140 and interconnect pad(s) 150 may be suitably configured to assist in coupling another device (e.g., MEMS device 200) to IC device 100.

Die seal ring 130, interconnect pad(s) 140, and interconnect pad(s) 150, in one embodiment, are each formed from the same material. In another embodiment, at least two of die seal ring 130, interconnect pad(s) 140, and interconnect pad(s) 150 are formed from different materials. In yet another embodiment, die seal ring 130, interconnect pad(s) 140, and interconnect pad(s) 150 are each formed from different materials.

In another embodiment, IC device 100 includes a passivation layer 160 forming a front surface 165 of IC device 100. Passivation layer 160 may be formed from any material known in the art or developed in the future capable of protecting IC device 100 from, for example, physical damage or corrosion. Examples of passivation layer 160 include, but are not limited to, silicon-nitride, silicon-oxy nitride, ceramic, an epoxy or other polymeric or dielectric material, and various glass and/or plastic filler materials.

Notably, the various embodiments of IC device 100 discussed above are capable of being coupled to another semiconductor device. In accordance with one exemplary embodiment, IC device 100 is capable of being coupled to a MEMS device 200.

FIG. 2 is a diagram of one embodiment of MEMS device 200 including a substrate 210 that forms a back side 205 of MEMS device 200, wherein substrate 210 may comprise, for example, a ceramic, a glass, and/or a semiconductor (e.g., Si, SiGe, Ge, GaAs, and the like). MEMS device 200, in accordance with one exemplary embodiment, is a device such as a switch, an adjustable capacitor, a sensor, an accelerometer, a resonator, or any other type of MEMS device. In another embodiment, MEMS device 200 is an RF-MEMS device. When fabricated, MEMS device 200 is an unsealed MEMS device, which is capable of becoming sealed when suitably coupled to another device (e.g., IC device 100 via die seal ring 130).

In accordance with one embodiment, MEMS device 200 includes a conductive layer 220 disposed on substrate 210. Conductive layer 220 may be any conductive material capable of relaying a signal into and/or out of MEMS device 200.

MEMS device 200, in another embodiment, includes at least one via 235 formed in substrate 210. Each via 235 may be formed utilizing any suitable method and/or technique for forming a via. Moreover, via(s) 235 may be suitably configured to connect MEMS device 200 to an external device and relay signals into and/or out of MEMS device 200.

As illustrated in FIG. 2, each via 235 is fabricated so that it extends partially through substrate 210. Eventually, a portion of substrate 210 is removed such that at least one via 235 extends substantially through substrate 210. Although FIG. 2 illustrates that vias 235 initially extend partially through substrate 210, various embodiments contemplate that MEMS device 200 may be fabricated with one or more vias 235 extending completely through or substantially through substrate 210.

In another embodiment, MEMS device 200 includes at least one conductive layer 225 disposed over conductive layer 220. Conductive layer 225 may be formed from any conductive material capable of transmitting a signal. In accordance with one embodiment, conductive layer 225 is a copper-plated material. Conductive layer 225, in another embodiment, is a tin-plated material. In yet another embodiment, conductive layer 225 is a gold-plated material.

MEMS device 200, in yet another embodiment, includes at least one additional conductive layer 215 disposed over conductive layer 220, wherein conductive layer 215 forms a front surface 265 of MEMS device 200. Conductive layer 215 may be formed from any material capable of forming an electrical connection with interconnect 140 and/or 150, and forming a hermetic or vacuum seal with die seal ring 130. In accordance with one embodiment, conductive layer 215 is a copper-plated material. Conductive layer 215, in another embodiment, is a tin-plated material. In yet another embodiment, conductive layer 215 is a gold-plated material.

In accordance with one embodiment, conductive layer 225 and conductive layer 215 are comprised of substantially the same material. In another embodiment, conductive layer 225 and conductive layer 215 are comprised of different materials. Conductive layer 225 and conductive layer 215, in yet another embodiment, form a single conductive layer when they are formed of the same material.

Conductive layer 215, conductive layer 220, and conductive layer 225, in one exemplary embodiment, form a MEMS seal ring 230 extending around the perimeter of substrate 210. Moreover, conductive layer 215, conductive layer 220, and conductive layer 225 form one or more interconnects 240 and/or one or more interconnects 250 configured to at least assist in mechanically and/or electrically coupling MEMS device 200 to another device. For example, MEMS device 200 is capable of being coupled to IC device 100 by die seal ring 130 and MEMS seal ring 230. Moreover, MEMS device 200 is capable of being additionally coupled to IC device 100 by interconnect(s) 140 and interconnect(s) 240 and/or interconnect(s) 150 and interconnect(s) 250 when die seal ring 130 and MEMS seal ring 230 couple IC device 100 to MEMS device 200.

MEMS device 200, in one embodiment, includes a cantilever structure 260. In one embodiment, cantilever structure 260 includes an end 262 mechanically coupled to conductive layer 220 such that a distal end 268 experiences up-and-down movement with respect to an electrode 220a of conductive layer 220. Cantilever structure 260 may be formed of any or combination of materials, including, for example, aluminum, tungsten, nickel, copper, silicon, poly-silicon, silicon dioxide, silicon nitride, silicon oxy-nitride, diamond, and other dielectrics, and the like materials. Moreover, other embodiments of MEMS device 200 may include other MEMS structures.

FIG. 3 is a diagram of one embodiment of a semiconductor device 300 comprising IC device 100 and MEMS device 200 in a three-dimensional structure. In accordance with one embodiment, semiconductor device 300 includes a three-dimensional structure formed by coupling front surface 165 to front surface 265.

As illustrated in the embodiment of FIG. 3, die seal ring 130 is coupled to MEMS seal ring 230, interconnect pad(s) 140 are coupled to interconnect pad(s) 240, and interconnect pad(s) 150 are coupled to interconnect pad(s) 250. In accordance with one embodiment, MEMS seal ring 230 is coupled to die seal ring 130 and MEMS device 200 is sealed to IC device 100 when MEMS device 200 is coupled to IC device 100.

MEMS device 200, in one embodiment, is hermetically sealed when coupled to IC device 100 utilizing MEMS seal ring 230 and die seal ring 130. In another embodiment, MEMS device 200 is vacuum sealed when coupled to IC device 100 utilizing MEMS seal ring 230 and die seal ring 130.

FIG. 4 is a diagram illustrating one embodiment of a three-dimensional semiconductor device 400 comprised of semiconductor device 300 and at least one passive device disposed on back surface 205. As illustrated, semiconductor device 400 includes at least one passive device built on back surface 205 utilizing, for example, thin film deposition and/or etch technique, as known in the art. The passive device(s) may be, for example, a resistive element (e.g., a resistor), a capacitive element (e.g., a capacitor), an inductive element (e.g., an inductor), a filter, a resonating element (e.g., a resonator), a coupler, and/or the like device(s).

In the embodiment illustrated in FIG. 4, semiconductor device 400 includes a capacitive element 450 comprised of conductive layer 454 and conductive layer 458, wherein conductive layer 454 is coupled to substrate 210 and separated from conductive layer 458 by a dielectric 460. Moreover, conductive layer 458 is coupled to a dielectric layer 410, wherein dielectric layers 410 and 460 may be formed from a known dielectric material including, for example, silicon dioxide, silicon nitride, silicon oxy-nitride, or any other suitable dielectric material. Moreover, semiconductor device 400 includes dielectric layer 410 coupled to a dielectric layer 440, wherein dielectric layer 440 is formed from, for example, silicon dioxide, silicon nitride, silicon oxy-nitride, or any other suitable dielectric material.

In one embodiment, semiconductor device 400 includes a conductive layer 425 disposed on dielectric layer 410. In accordance with one embodiment, the exposed surfaces of conductive layer 425 are plated with a copper material. The exposed surfaces of conductive layer 425, in another embodiment, are plated with a tin material. In yet another embodiment, the exposed surfaces of conductive layer 425 are plated with a gold material.

In accordance with one embodiment, a portion 425d of conductive layer 425 forms an inductive element 475 disposed between dielectric layer 440 and dielectric layer 410. In the embodiment illustrated in FIG. 4, inductive element 475 is coupled to conductive layer 458 of capacitive element 450.

Notably, although the embodiment illustrated in FIG. 4 includes capacitive element 450 and inductive element 475, semiconductor device 400 may include a fewer number or a greater number of passive devices disposed on MEMS device 200. In addition, the passive devices may be the same type or different types of passive elements. Moreover, although semiconductor device 400 has been described as including capacitive element 450 and inductive element 475; as noted above, semiconductor device 400 may include any other type(s) of passive device(s).

Semiconductor device 400, in one embodiment, includes a via 435a coupled to a conductive pad 425a, a via 435b coupled to a conductive pad 425b, and a via 435c coupled to a conductive pad 425c, wherein vias 435a, 435b, and 435c are formed utilizing any known technique for forming a via. In accordance with one embodiment, conductive pad 425a is coupled to a solder ball 438a, conductive pad 425b is coupled to a solder ball 438b, and conductive pad 425c is coupled to a solder ball 438c.

Solder balls 438a, 438b, and 438c are configured to couple semiconductor device 400 to another structure (e.g., a substrate 510 discussed below) and/or another device (e.g., a controller, not shown). Moreover, solder balls 438a and 438b are configured to receive signals from the device, wherein the signals may be any known signal type. In one embodiment, solder balls 438a and 438b are configured to receive DC signals from the controller when semiconductor device 400 is coupled to the controller. In another embodiment, solder ball 438a is configured to receive analog signals and solder ball 438b is configured to receive digital signals.

In addition, solder ball 438c is configured to couple semiconductor device 400 to another structure (e.g., a substrate 510 discussed below) and/or another system (not shown). Moreover, solder ball 438c is configured to receive signals from the system, wherein the signals may be any known signal type. In one embodiment, solder ball 438c is configured to receive radio frequency (RF) signals (which are controlled, interrupted, re-directed, attenuated, etc. by MEMS device 200) from the system when semiconductor device 400 is coupled to the system. Accordingly, semiconductor 400 includes separate RF signal path 486 and signal paths 482 and 484, wherein signal paths 482 and 484 may each be either an analog signal path or a digital signal path such that signal paths 482 and 484 may be the same type of signal path or different types of signal paths.

As discussed above, semiconductor device 400 includes separate CMOS control signal and RF signals. Accordingly, various embodiments of IC device 100 may not experience the interference associated with CMOS devices processing RF signals.

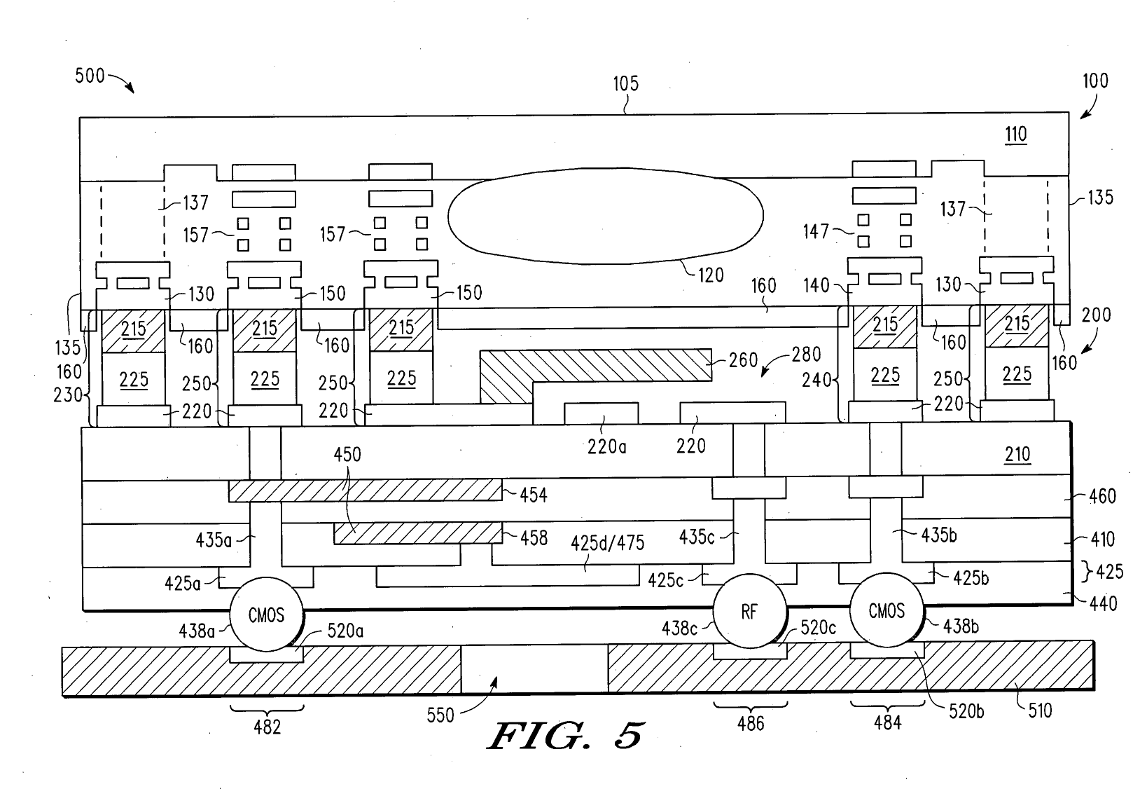

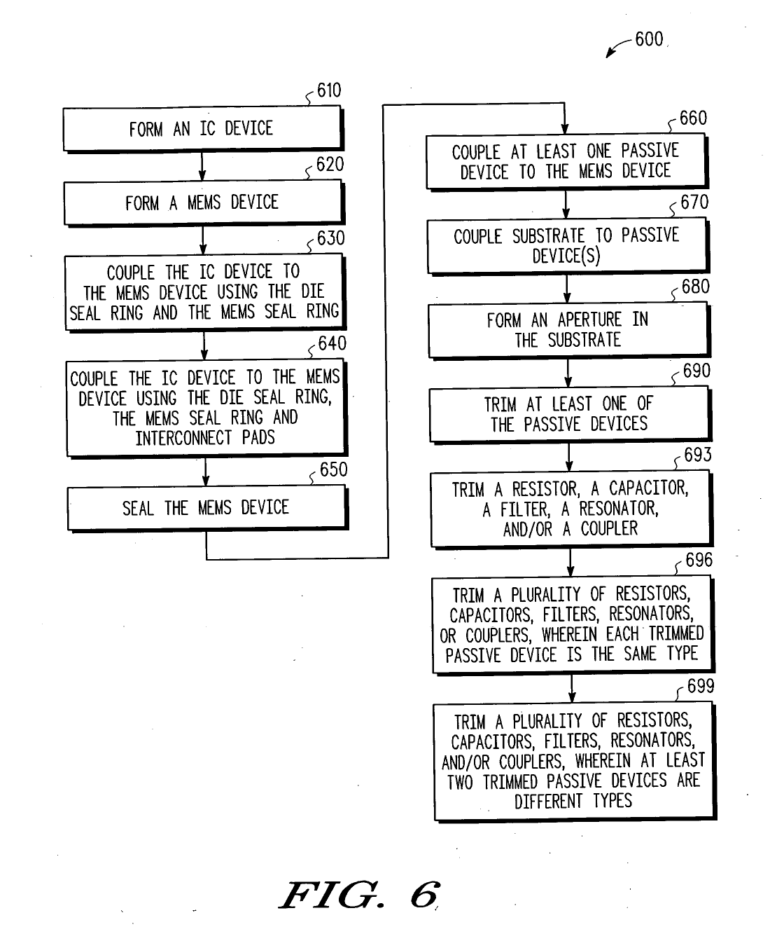

FIG. 5 is a diagram of one embodiment of a semiconductor device 500 comprising semiconductor device 400 and including a structure which enables one or more passive devices to be trimmed after the passive device(s) is/are disposed on MEMS device 200. In one embodiment, semiconductor device 500 includes a substrate 510 formed of a dielectric material, wherein substrate 510 includes conductive pads 520a, 520b, and 520c disposed thereon. Moreover, conductive pads 520a, 520b, and 520c are coupled to solder balls 438a, 438b, and 438c, respectively.

In accordance with one embodiment, substrate 510 includes at least one aperture 550 extending substantially through substrate 510. Aperture 550, in one embodiment, is suitably configured to be proximate to at least one passive device and include dimensions such that at least a portion of the passive device(s) may be trimmed (e.g., removed) by, for example, a laser. In the embodiment illustrated in FIG. 5, aperture 550 is oriented proximate to capacitive element 450. Accordingly, during and/or after manufacture of semiconductor device 500 should capacitive element 450 include too much capacitance, capacitive element 450 may be trimmed such that capacitive element 450 includes the desired amount of capacitance.

Notably, although the embodiment illustrated in FIG. 5 includes capacitive element 450 and inductive element 475, semiconductor device 500 may include more or fewer passive devices disposed on MEMS device 200. In addition, the passive device(s) may be the same or different types of passive elements. Moreover, although semiconductor device 500 has been described as including capacitive element 450 and inductive element 475; as noted above, semiconductor device 500 may include any other type(s) of passive device(s). Accordingly, any number of passive devices disposed on MEMS device 200 may be trimmed during manufacture and/or after manufacture utilizing, for example, a laser through aperture 550. Furthermore, various embodiments contemplate that semiconductor 500 may include more than one aperture 550 to trim passive devices oriented at various locations on MEMS device 200.

FIG. 6 is a flow diagram illustrating one embodiment of a method 600 to produce an integrated IC/MEMS semiconductor device (e.g., semiconductor device 300, 400, and/or 500). In accordance with one embodiment, method 600 initiates by forming an IC device (e.g., IC device 100) (block 610). In one embodiment, forming IC device 100 includes forming a die seal ring (e.g., die seal ring 130) configured to protect IC device 100 during manufacture and couple IC device 100 to at least one other device (e.g., MEMS device 200). Forming die seal ring 130, in another embodiment, also includes forming one or more interconnect pads (e.g., interconnect pads 140 and 150) configured to assist die seal ring 130 in coupling IC device 100 to MEMS device 200.

Method 600, in another embodiment, includes forming a MEMS device (e.g., MEMS device 200) (block 620). In accordance with one embodiment, forming MEMS device 200 includes forming a MEMS seal ring (e.g., MEMS seal ring 230) suitably configured to couple MEMS device 200 to an IC device (e.g., IC device 100) via MEMS seal ring 230 and a die seal ring (e.g., die seal ring 130). Forming MEMS device 200, in another embodiment, also includes forming one or more interconnect pads (e.g., interconnect pads 240 and 250) configured to assist MEMS seal ring 230 in coupling MEMS device 200 to IC device 100. In yet another embodiment, forming MEMS device 200 includes forming an RF signal path (e.g., RF signal path 486) and/or at least one other separate signal path (e.g., signal path 484 and 488 on the integrated IC/MEMS semiconductor device. In an alternate embodiment, forming MEMS device 200 includes forming a plurality of signal paths. In another alternate embodiment, forming MEMS device 200 includes forming at least one analog signal path and at least one digital signal path.

Method 600, in one embodiment, includes coupling MEMS device 200 to IC device 100 via die seal ring 130 and MEMS seal ring 230 (block 630). In another embodiment, method 600 includes coupling device 200 to IC device 100 via a die seal ring 130 and MEMS seal ring 230, and via one or more IC device interconnect pads (e.g., interconnect pads 140 and 150) and one or more MEMS device interconnect pads (e.g., interconnect pads 140 and 150) (block 640).

Coupling MEMS device 200 to IC device 100, in one embodiment, includes sealing MEMS device 200 when MEMS device 200 and IC device 100 are coupled together (block 650). In one embodiment, sealing includes hermetically sealing MEMS device 200 (e.g., forming an air tight bond between MEMS device 200 and IC device 100) when MEMS device 200 is coupled to IC device 100. In another embodiment, sealing includes vacuum sealing MEMS device 200 (e.g., sealing MEMS device 200 in a vacuum) when MEMS device 200 is coupled to IC device 100.

Method 600, in one embodiment, includes coupling at least one passive device (e.g., a resistor, a capacitor, a coupler, a filter, and/or a resonator) to MEMS device 200 (block 660). In one embodiment, coupling the at least one passive device to MEMS device 200 includes coupling the passive device to MEMS device 200 prior to coupling MEMS device 200 to IC device 100. In another embodiment, coupling the at least one passive device to MEMS device 200 includes coupling the passive device to MEMS device 200 after coupling MEMS device 200 to IC device 100.

In yet another embodiment, method 600 includes coupling a substrate (e.g., substrate 510) to the at least one passive device (block 670). Moreover, method 600 includes forming at least one aperture (e.g., aperture 550) in substrate 510 (block 680).

Method 600, in still another embodiment, includes trimming one or more of the passive devices after coupling the substrate to the one or more passive devices (block 690). In one embodiment, trimming includes trimming a resistor, a capacitor, a filter, a resonator, and/or a coupler (block 693). In another embodiment, trimming includes trimming a plurality of resistors, capacitors, filters, resonators, or couplers, wherein the trimmed passive devices are the same type of passive device (block 696). In yet another embodiment, trimming includes trimming a plurality of resistors, capacitors, filters, resonators, and couplers, wherein the trimmed passive devices are different types of passive devices (block 699).

In summary, various embodiments provide a semiconductor device comprising an integrated circuit (IC) device having a die seal ring and a micro-electro-mechanical systems (MEMS) device having a MEMS seal ring, wherein the IC device is coupled to the MEMS device via the die seal ring and the MEMS seal ring. In one embodiment, the MEMS device further comprises a back surface and at least one passive device coupled to the back surface. The semiconductor device, in another embodiment, includes a substrate including at least one aperture extending substantially through the substrate coupled to the MEMS device such that the at least one passive device is disposed between the substrate and the MEMS device. In yet another embodiment, the at least one passive device is one of a resistor, a capacitor, a coupler, a filter, and a resonator. In still another embodiment, the aperture is configured such that the one of the resistor, the capacitor, the resonator, the filter, and the coupler is trim-able when the substrate is coupled to the MEMS device.

The MEMS device, in one embodiment, includes separate DC signal and RF signal paths. In another embodiment, the MEMS device includes a first signal path and a second signal path, and the IC device includes a third signal path coupled to the first signal path and a fourth signal path coupled to the second signal path, wherein the first and third signal paths are configured to relay analog signals and the second and fourth signal paths are configured to relay digital signals.

In another embodiment, the die seal ring and the MEMS seal ring are configured to enable the MEMS device to be sealed when the MEMS device is coupled to the IC device. In an alternate embodiment, the MEMS device is one of hermetically sealed and vacuum sealed when coupled to the IC device.

The IC device, in one embodiment, is one of a gallium arsenide device, a complementary metal oxide semiconductor (CMOS) device, and a bi-polar complementary metal oxide semiconductor (Bi-CMOS) device. In another embodiment, the MEMS device is an RF-MEMS device when the IC device is one of a gallium arsenide device, a complementary metal oxide semiconductor (CMOS) device, and a bi-polar complementary metal oxide semiconductor (Bi-CMOS) device.

Various embodiments also provide a method for producing a semiconductor device. In one embodiment, the method includes forming an integrated circuit (IC) device having a die seal ring, forming a micro-electro-mechanical systems (MEMS) device having a MEMS seal ring, and coupling the IC device to the MEMS device via the die seal ring and MEMS seal ring. In another embodiment, the method includes sealing the MEMS device when the MEMS device and the IC device are coupled to one another, wherein sealing comprises one of hermetically sealing and vacuum sealing the MEMS device when coupling the MEMS device to the IC device.

In one embodiment wherein the MEMS device further comprises a back surface, the method further includes coupling at least one passive device to the back surface. Coupling the at least one passive device to the back surface, in one embodiment, occurs prior to coupling the MEMS device to the IC device. Coupling the at least one passive device to the back surface, in another embodiment, occurs after coupling the MEMS device to the IC device.

The method, in another embodiment, includes coupling a substrate to the at least one passive device. In yet another embodiment, the method further includes forming at least one aperture substantially through the substrate. In still another embodiment, the method includes trimming the at least one passive device after disposing the substrate on the MEMS device. In an alternate embodiment, trimming includes trimming at least one of a resistor, a capacitor, a coupler, a filter, and a resonator.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration in any way. Rather, the foregoing detailed description will provide those skilled in the art with a convenient road map for implementing an exemplary embodiment, it being understood that various changes may be made in the function and arrangement of elements described in an exemplary embodiment without departing from the scope of the embodiment as set forth in the appended claims and their legal equivalents.

1. A semiconductor device comprising:
an integrated circuit (IC) device having a die seal ring;
a micro-electro-mechanical systems (MEMS) device including a MEMS seal ring and a back surface, wherein the IC device is coupled to the MEMS device via coupling the die seal ring and the MEMS seal ring;
a first passive device coupled to the back surface; and
a substrate coupled to the passive device such that the first passive device is disposed between the substrate and the back surface, the substrate including at least one aperture extending through the substrate and configured to enable the first passive device to be trimmed when coupled to the back surface.

2-3. (canceled)

4. The semiconductor device of claim 1, wherein the first passive device is one of a resistor, a capacitor, a coupler, a filter, and a resonator.

5. (canceled)

6. The semiconductor device of claim 1, wherein the MEMS device includes separate DC signal and RF signal paths.

7. The semiconductor device of claim 1, wherein the MEMS device includes a first signal path and a second signal path, and the IC device includes a third signal path coupled to the first signal path and a fourth signal path coupled to the second signal path, wherein the first and third signal paths are configured to relay analog signals and the second and fourth signal paths are configured to relay digital signals.

8. The semiconductor device of claim 1, wherein the die seal ring and the MEMS seal ring are configured to enable the MEMS device to be sealed when the MEMS device is coupled to the IC device.

9. The semiconductor device of claim 8, wherein the MEMS device is one of hermetically sealed and vacuum sealed when coupled to the IC device.

10. The semiconductor device of claim 1, wherein the IC device is one of a gallium arsenide device, a complementary metal oxide semiconductor (CMOS) device, and a bi-polar complementary metal oxide semiconductor (Bi-CMOS) device.

11. (canceled)

12. A method of producing a semiconductor device, comprising:
forming an integrated circuit (IC) device including a die seal ring;
forming a micro-electro-mechanical systems (MEMS) device including a MEMS seal ring and a back surface;
coupling the die seal ring to the MEMS seal ring;
coupling at least one passive device to the back surface;
coupling a substrate to the at least one passive device such that the at least one passive device is disposed between the substrate and the back surface;
forming an aperture in the substrate; and
trimming the at least one passive device via the aperture.

13. (canceled)

14. The method of claim 12, wherein coupling the at least one passive device to the back surface occurs prior to coupling the MEMS device to the IC device.

15. The method of claim 12, wherein coupling the at least one passive device to the back surface occurs after coupling the MEMS device to the IC device.

16-18. (canceled)

19. The method of claim 12, wherein trimming comprises trimming at least one of a resistor, a capacitor, a coupler, a filter, and a resonator.

20. The method of claim 12, further comprising sealing the MEMS device when the MEMS device and the IC device are coupled to one another, wherein sealing comprises one of hermetically sealing and vacuum sealing the MEMS device when coupling the MEMS device to the IC device.

21. The semiconductor device of claim 1, further comprising a second passive device coupled to the back surface and the substrate such that the second passive device is disposed between the substrate and the back surface, wherein the aperture is further configured to enable the second passive device to be trimmed when coupled to the back surface.

22. The semiconductor of claim 21, wherein the first passive device and the second passive device are each one of a resistor, a capacitor, a coupler, a filter, and a resonator.

23. The semiconductor device of claim 22, wherein the first passive device and the second passive device are different passive devices.

24. The method of claim 12, wherein the aperture is formed before the substrate is coupled to the at least one passive device.

25. The method of claim 12, wherein the aperture is formed after the substrate is coupled to the at least one passive device.

26. A method of producing a semiconductor device, comprising:
forming a micro-electro-mechanical systems (MEMS) device including a back surface;
coupling at least one passive device to the back surface;
coupling a substrate to the at least one passive device such that the at least one passive device is disposed between the substrate and the back surface;
forming an aperture in the substrate; and
trimming the at least one passive device via the aperture.

27. The method of claim 26, wherein the aperture is formed after the substrate is coupled to the at least one passive device.

28. The method of claim 26, wherein the aperture is formed before the substrate is coupled to the at least one passive device.
